(19) United States
(12) Patent Application Publication
(10) Pub. No.: US 2025/0350217 A1
(43) Pub. Date: Nov. 13, 2025

(54) DISPLAY APPARATUS, DISPLAY PANEL MOVEMENT CONTROL METHOD AND APPARATUS, MEDIUM, AND DEVICE

(71) Applicant: BOE Technology Group Co., Ltd., Beijing (CN)

(72) Inventors: Ke FENG, Beijing (CN); Sitong CHEN, Beijing (CN); Zongyuan WANG, Beijing (CN)

(73) Assignee: BOE Technology Group Co., Ltd., Beijing (CN)

(21) Appl. No.: 18/871,486

(22) PCT Filed: Jul. 17, 2023
(86) PCT No.: PCT/CN2023/107784

§ 371 Date: Dec. 4, 2024

(30) Foreign Application Priority Data
Jul. 25, 2022 (CN) 202210884597.5

(51) Int. Cl. H02P 8/34; G06F 1/16; H05K 5/02

(52) U.S. Cl. CPC H02P 8/34; G06F 1/1652; H05K 5/0217

(57) ABSTRACT

A display apparatus, includes: a flexible display panel; a power device, connected to the flexible display panel, where the power device drives the flexible display panel to move in response to a driving signal; and a control device, connected to the power device, where the control device is used to control the power device to operate at a first rate in a first movement stage of the flexible display panel, and control the power device to operate at a second rate in a second movement stage of the flexible display panel, and the second rate is greater than the first rate.

### CROSS-REFERENCE TO RELATED APPLICATIONS

The present application is a U.S. national stage of International Application No. PCT/CN2023/107784, filed on Jul. 17, 2023, and claims priority to Chinese Patent Application No. 202210884597.5, entitled “Display apparatus and Method for display panel movement control, Apparatus, Medium, and Device,” filed on Jul. 25, 2022, the entire contents of both of which are incorporated herein by reference in their entirety.

### TECHNICAL FIELD

The present disclosure relates to the field of display technology, and in particular, to a display apparatus and a method for display panel movement control, an apparatus, a medium, and a device.

### BACKGROUND

With the continuous development of display technology, due to the bendable characteristics of the materials and structures, organic light-emitting diode (OLED) display apparatuses provide a possibility for the diversity of appearance and modality of products, such as a curved display apparatus and a display apparatus that can perform sliding and curling.

It should be noted that the information disclosed in the above background part is only used to enhance the understanding of the background of the present disclosure, and therefore may include information that does not constitute related art known to those of ordinary skill in the art.

### SUMMARY

An objective of the present disclosure is to overcome the shortcomings of the related art, and provide a display apparatus, a method for display panel movement control, an apparatus, a medium, and a device.

According to an aspect of the present disclosure, there is provided a display apparatus, including: a flexible display panel; a power device, connected to the flexible display panel, where the power device drives the flexible display panel to move in response to a driving signal; and a control device, connected to the power device, where the control device is used to control the power device to operate at a first rate in a first movement stage of the flexible display panel, and control the power device to operate at a second rate in a second movement stage of the flexible display panel, and the second rate is greater than the first rate.

In some embodiments of the present disclosure, the display apparatus includes a push rod connected to the flexible display panel; the power device includes a motor, and a power end of the motor is connected to the push rod to drive the flexible display panel through the push rod; and the control device includes: a motor driving circuit, connected to the motor, where the motor driving circuit outputs a driving signal to the motor in response to a control signal; and a motor controller, connected to the motor driving circuit, where the motor controller is used to: control, in the first movement stage, the motor to operate at a first rotation rate to drive the flexible display panel connected to the push rod to move; obtain an actual rotation rate of the motor in real time; if the actual rotation rate of the motor is less than the first rotation rate, control the motor driving circuit to output a driving signal for increasing a driving force to the motor, to cause a rotation rate of the motor to match with the first rotation rate; detect, based on the driving signal, whether the flexible display panel completes the first movement stage; and if the flexible display panel completes the first movement stage, control the motor to operate at a second rotation rate, until the flexible display panel completes a second movement stage, where the second rotation rate is greater than the first rotation rate.

In some embodiments of the present disclosure, the control signal includes a rotation rate control signal and a power control signal, the rotation rate control signal is used for adjusting a frequency of the driving signal, and the power control signal is used for adjusting an amplitude of the driving signal; the motor controller is used to output the rotation rate control signal and the power control signal; the control device further includes a power source driving circuit, the power source driving circuit is connected to the motor controller and the motor driving circuit respectively, and the power source driving circuit is used to output a corresponding voltage signal in response to the power control signal; and the motor driving circuit is further used to determine the frequency of the driving signal in response to the rotation rate control signal, determine the amplitude of the driving signal in response to the voltage signal, and output a corresponding driving signal.

In some embodiments of the present disclosure, the display apparatus further includes a temperature sensor connected to the motor controller, and the temperature sensor is used to detect an ambient temperature of the display apparatus and output a temperature indication signal to the motor controller; the motor controller is further used to: determine a current temperature based on the obtained temperature indication signal; compare the current temperature with a preset temperature threshold; and if the current temperature is less than or equal to the temperature threshold, output a rotation rate control signal with a reduced pulse frequency to the motor driving circuit, and/or output a power control signal with an increased pulse number to the power source driving circuit; the power source driving circuit is further used to output a voltage signal with an increased amplitude in response to the power control signal with the increased pulse number; and the motor driving circuit is further used to: determine an adjusted frequency of the driving signal in response to the rotation rate control signal with the reduced pulse frequency, and/or determine an adjusted amplitude of the driving signal in response to the voltage signal with the increased amplitude, and output the adjusted driving signal.

In some embodiments of the present disclosure, the display apparatus further includes a distance sensor connected to the motor controller, and the distance sensor is used to detect a distance between a fixed end and a movable end of the flexible display panel, and output a distance indication signal to the motor controller; the motor controller is further used to: determine a movement distance of the flexible display panel based on the distance indication signal; determine a current rotation rate of the motor based on the movement distance and a movement duration; compare the current rotation rate with the first rotation rate; and if a rotation rate difference between the current rotation rate and the first rotation rate is greater than or equal to a preset rotation rate threshold, output a rotation rate control signal with a reduced pulse frequency to the motor driving circuit, and/or output a power control signal with an increased pulse number to the power source driving circuit; the power source driving circuit is further used to output a voltage signal with an increased amplitude in response to the power control signal with the increased pulse number; and the motor driving circuit is further used to: determine an adjusted frequency of the driving signal in response to the rotation rate control signal with the reduced pulse frequency, and/or determine an adjusted amplitude of the driving signal in response to the voltage signal with the increased amplitude, and output the adjusted driving signal, where an actual rotation rate of the motor in response to the adjusted driving signal matches with the first rotation rate.

In some embodiments of the present disclosure, the motor controller is further used to: calculate a pulse number of the rotation rate control signal that is output cumulatively; determine a movement distance of the flexible display panel based on the pulse number and a rotation rate of the motor; compare the movement distance of the flexible display panel with a distance value of the first movement stage; if the movement distance of the flexible display panel is equal to the distance value of the first movement stage, determine that the flexible display panel completes the first movement stage; or if the movement distance of the flexible display panel is less than the distance value of the first movement stage, determine that the flexible display panel is in the first movement stage.

In some embodiments of the present disclosure, the motor is a stepping motor.

In some embodiments of the present disclosure, both the rotation rate control signal and the power control signal include periodic pulse signals.

In some embodiments of the present disclosure, a ratio of the first rotation rate to the second rotation rate is greater than or equal to 0.5 and less than 1.

According to a second aspect of the present disclosure, there is further provided a method for display panel movement control, applied to the display apparatus according to any embodiment of the present disclosure, the method being performed by a control device, and the method including: controlling the power device to operate at a first rate in a first movement stage; and controlling the power device to operate at a second rate in a second movement stage, where the second rate is greater than the first rate.

In some embodiments of the present disclosure, the method includes: controlling, in the first movement stage, the motor to operate at a first rotation rate; obtaining an actual rotation rate of the motor in real time; if the actual rotation rate of the motor is less than the first rotation rate, controlling the motor driving circuit to output a driving signal for increasing a driving force to the motor to cause a rotation rate of the motor to match with the first rotation rate; detecting, based on the driving signal, whether the flexible display panel completes the first movement stage; and if the flexible display panel completes the first movement stage, controlling the motor to operate at a second rotation rate, until the flexible display panel completes a second movement stage, where the second rotation rate is greater than the first rotation rate.

In some embodiments of the present disclosure, the display apparatus further includes a distance sensor, and the distance sensor is used to detect a distance between a fixed end and a movable end of the flexible display panel; and obtaining the actual rotation rate of the motor in real time includes: obtaining a distance indication signal output by the distance sensor in real time; determining a movement distance of the flexible display panel based on the distance indication signal; and determining the actual rotation rate of the motor based on the movement distance and a movement duration.

In some embodiments of the present disclosure, after determining the actual rotation rate of the motor based on the movement distance and the movement duration, the method further includes: comparing the current rotation rate with the first rotation rate; and if a rotation rate difference between the current rotation rate and the first rotation rate is greater than or equal to a preset rotation rate threshold, determining that the actual rotation rate of the motor is less than the first rotation rate.

In some embodiments of the present disclosure, the display apparatus includes a power source driving circuit and a motor driving circuit, the power source driving circuit is connected to the motor controller and the motor driving circuit respectively, the motor driving circuit is connected to the motor controller and the motor respectively, and controlling the motor driving circuit to output the driving signal for increasing the driving force to the motor, including: outputting a rotation rate control signal with a reduced pulse frequency to the motor driving circuit, and/or outputting a power control signal with an increased pulse number to the power source driving circuit, where the power control signal is used to instruct the motor driving circuit to output a driving signal with an increased amplitude.

In some embodiments of the present disclosure, detecting, based on the driving signal, whether the flexible display panel completes the first movement stage, includes: calculating a pulse number of the rotation rate control signal that is output cumulatively; determining a movement distance of the flexible display panel based on the pulse number and a rotation rate of the motor; comparing the movement distance of the flexible display panel with a distance value of the first movement stage; if the movement distance of the flexible display panel is equal to the distance value of the first movement stage, determining that the flexible display panel completes the first movement stage; or if the movement distance of the flexible display panel is less than the distance value of the first movement stage, determining that the flexible display panel is in the first movement stage.

In some embodiments of the present disclosure, controlling the motor to operate at the first rotation rate includes controlling the motor driving circuit to output a rotation rate control signal of a first frequency to the motor, where the rotation rate control signal of the first frequency is used to instruct the motor driving circuit to drive the motor to rotate at the first rotation rate.

In some embodiments of the present disclosure, controlling the motor to operate at the second rotation rate includes controlling the motor driving circuit to output a rotation rate control signal of a second frequency to the motor, where the second frequency is greater than the first frequency, and the rotation rate control signal of the second frequency is used to instruct the motor driving circuit to drive the motor to rotate at the second rotation rate.

In some embodiments of the present disclosure, the display apparatus further includes a temperature sensor, and the temperature sensor is used to detect an ambient temperature of the display apparatus; and, before controlling the motor to operate at the first rotation rate, the method further includes: obtaining a temperature indication signal output by the temperature sensor; determining a current temperature based on the temperature indication signal; and if the current temperature is less than a preset temperature threshold, controlling the motor driving circuit to output a driving signal for increasing a driving force to the motor, to cause an actual rotation rate of the motor to match with the first rotation rate.

In some embodiments of the present disclosure, controlling the motor driving circuit to output the driving signal for increasing the driving force to the motor includes: outputting a rotation rate control signal with a reduced pulse frequency to the motor driving circuit, and/or outputting a power control signal with an increased pulse number to the power source driving circuit, where the power control signal is used to instruct the motor driving circuit to output a driving signal with an increased amplitude.

According to a third aspect of the present disclosure, there is further provided an apparatus for display panel movement control, including: a first rotation rate control module, configured to control a power device to operate at a first rate in a first movement stage; and a second rotation rate control module, configured to control the power device to operate at a second rate, where the second rate is greater than the first rate.

According to a fourth aspect of the present disclosure, there is further provided a computer-readable storage medium, on which a computer program is stored; and when the program is executed by a processor, the method for display panel movement control according to any embodiment of the present disclosure is implemented.

According to a fifth aspect of the present disclosure, there is further provided a control device, including: one or more processors; and a storage apparatus, configured to store one or more programs; when the one or more programs are executed by the one or more processors, the one or more processors are caused to implement the method for display panel movement control according to any embodiment of the present disclosure.

In the display apparatus provided by the present disclosure, the control device may control the power device to operate at the first rate in the first movement stage of the flexible display panel; the control device performs determination on the movement stroke of the flexible display panel, and controls the power device to operate at the second rate when the flexible display panel is detected to complete the first movement stage; and the second rate is greater than the first rate. That is, the operation rate of the power device in the second movement stage is improved, so as to control the flexible display panel to complete the entire movement stroke within the set duration. In the present disclosure, the operation rate of the power device is controlled according to different stages based on the movement stroke of the flexible display panel, and the operation rate is reasonably controlled according to the thrust requirement of the movement stroke, thus solving the problem of insufficient driving force of the power device in the movement stroke of the flexible display panel in the related art.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of the description, illustrate embodiments consistent with the present disclosure and together with the description serve to explain the principles of the present disclosure. Obviously, the drawings in the following description are some embodiments of the present disclosure, and for those of ordinary skill in the art, other drawings can also be obtained from these drawings without creative efforts.

FIG. 1 is a schematic structural diagram of a display apparatus with no movement according to some embodiments of the present disclosure;

FIG. 2 is a schematic structural diagram of a display apparatus after movement according to some embodiments of the present disclosure;

FIG. 3 is a schematic diagram of connections between related devices in a display apparatus according to some embodiments of the present disclosure;

FIG. 4 is a schematic diagram of a correspondence between a frequency of the driving signal and a rotation rate control signal according to some embodiments of the present disclosure;

FIG. 5 is a schematic diagram of a correspondence between an amplitude of the driving signal and a power control signal according to some embodiments of the present disclosure;

FIG. 6 is a schematic diagram of adjustment of a rotation rate control signal according to some embodiments of the present disclosure;

FIG. 7 is a schematic diagram of adjustment of a power control signal according to some embodiments of the present disclosure;

FIG. 8 is a flowchart of a method for display panel movement control according to some embodiments of the present disclosure;

FIG. 9 is a sliding setting interface of a display apparatus provided according to some embodiments of the present disclosure;

FIG. 10 is a structural block diagram of an apparatus for display panel movement control according to some embodiments of the present disclosure;

FIG. 11 is a schematic structural diagram of a control device according to some embodiments of the present disclosure.

### DETAILED DESCRIPTION

Example embodiments will now be described more fully with reference to the accompanying drawings. Example embodiments, however, can be implemented in various forms and should not be construed as limited to the embodiments set forth herein; by contrast, these embodiments are provided so that the present disclosure will be thorough and complete, and will fully convey the concept of example embodiments to those skilled in the art. The matching reference numerals in the drawings denote the matching or similar structures, and thus their detailed descriptions will be omitted. In addition, the drawings are merely schematic illustrations of the present disclosure and are not necessarily drawn to scale.

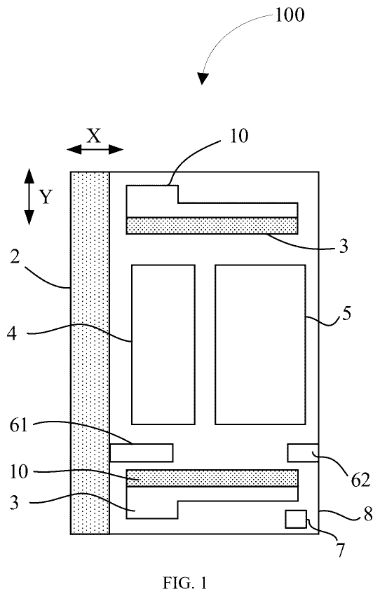

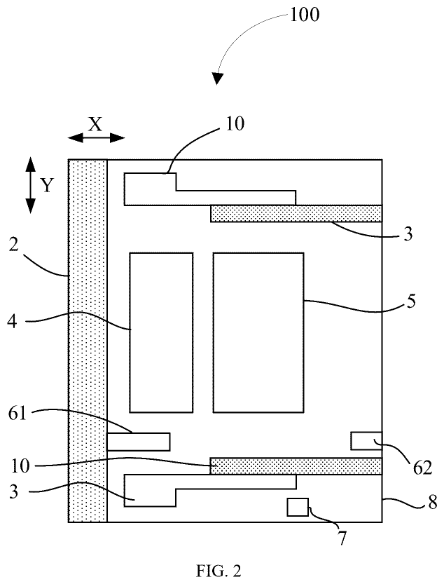

The present disclosure provides a display apparatus 100. FIG. 1 is a schematic structural diagram of a display apparatus with no movement according to some embodiments of the present disclosure. FIG. 2 is a schematic structural diagram of a display apparatus after movement according to some embodiments of the present disclosure. As shown in FIG. 1 and FIG. 2, the display apparatus 100 may include a flexible display panel 8, a power device 10, and a control device 4, where the power device 10 is connected to the flexible display panel 8, the power device 10 may drive the flexible display panel 8 to move in response to a driving signal, and the control device 4 is connected to the power device 10. The control device 4 may be used to: in a first movement stage of the flexible display panel 8, control the power device 10 to operate at a first rate; and in a second movement stage of the flexible display panel 8, control the power device 10 to operate at a second rate, where the second rate is greater than the first rate.

In the display apparatus 100 provided by the present disclosure, in the first movement stage of the flexible display panel 8, the control device 4 may control the power device 10 to operate at the first rate; the control device 4 performs determination on the movement stroke of the flexible display panel 8; and when the flexible display panel 8 is detected to complete the first movement stage, the control device 4 controls the power device 10 to operate at the second rate, and the second rate is greater than the first rate. That is, the operation rate of the power device 10 in the second movement stage is improved, so as to control the flexible display panel 8 to complete the entire movement stroke within a set duration. In the present disclosure, the operation rate of the power device 10 is controlled according to different stages based on the movement stroke of the flexible display panel 8, and the operation rate is reasonably controlled according to the thrust requirement of the movement stroke, thus solving the problem of insufficient driving force of the power device 10 in the movement stroke of the flexible display panel 8 in the related art.

As shown in FIG. 1, in some embodiments, the power device 10 may drive the flexible display panel 8 to move in the first direction X in the figure, and the power device 10 may drive the flexible display panel 8 to move to change the display area of the flexible display panel 8. Of course, in other embodiments, the flexible display panel 8 may also move along the second direction Y in the figure, which is specifically set according to the structure of the display apparatus 100.

The first movement stage of the flexible display panel 8 refers to a stage in which the flexible display panel 8 starts to move from an initial state to a set distance, and the second movement stage of the flexible display panel 8 is the remaining movement stage. The matching set distance may be determined from empirical values according to the specific structure of the display apparatus. For example, in the sliding and curling process of the flexible display panel 8, the first movement stage is an initial stage in which the flexible display panel 8 transitions from the curled state to the tiled state or an initial stage in which the flexible display panel 8 transitions from the tiled state to the curled state, and the sliding and curling distance in the initial stage is the set distance. The second movement stage is the remaining stage of the movement.

It should be noted that the movement of the flexible display panel 8 described in the present disclosure includes, but is not limited to, various movement modes such as sliding and curling, telescoping and folding of the flexible display panel 8. For example, for the foldable display apparatus 100, the movement of the flexible display panel 8 is folding and unfolding; and for the display apparatus 100 that can perform sliding and curling, the movement of the flexible display panel 8 is curling and stretching. When a picture needs to be displayed, the flexible display panel 8 may be moved to expand the display area; and when a picture does not need to be displayed, the flexible display panel 8 may be moved to reduce the occupied space, thus improving the applicability of the display apparatus 100 by using the characteristics of the flexible display panel 8. In the present disclosure, the structure of the display apparatus 100 and the movement process of the display apparatus 100 are exemplarily described only by taking the sliding and curling process of the flexible display panel 8 as an example.

It should be noted that the movement stage of the flexible display panel 8 of the present disclosure includes but is not limited to two movement stages. In some embodiments, the power device 10 may operate at the second rate until the stroke of the flexible display panel 8 is completed. In another example embodiment, the flexible display panel 8 may further be provided with a plurality of movement stages. For example, after the flexible display panel 8 completes the second movement stage, the control device may further control the power device 10 to perform N operations (N≥1) to drive the flexible display panel 8 to further complete N movement stages, and the rate for the Nth operation may be set according to requirements. For example, after driving the flexible display panel 8 to complete the second movement stage (for example, unfolding), the power device 10 may further drive the flexible display panel 8 to enter a third movement stage (N=1). In the third movement stage, the control device may control the power device 10 to reduce the operation rate to drive the flexible display panel 8 to gradually stop. For example, the power device 10 may operate at a third rate, and the third rate may be less than the second rate and greater than the first rate, or the third rate may be a gradually changed rate less than the second rate, etc., which all fall within the protection scope of the present disclosure. As shown in FIG. 1 and FIG. 2, in some embodiments, the display apparatus 100 may further include a push rod 3, and a power end of the power device 10 is connected to the push rod 3 to drive the flexible display panel 8 to move along the first direction X in the figure through the push rod 3. In addition, the display apparatus may further include a battery 5 and a housing 2, and the battery 5 supplies power to related devices such as the power device 10 and the control device 4. The housing 2 may be used for holding. In addition, the power device 10 of the present disclosure may include one or more devices such as a motor and a cylinder.

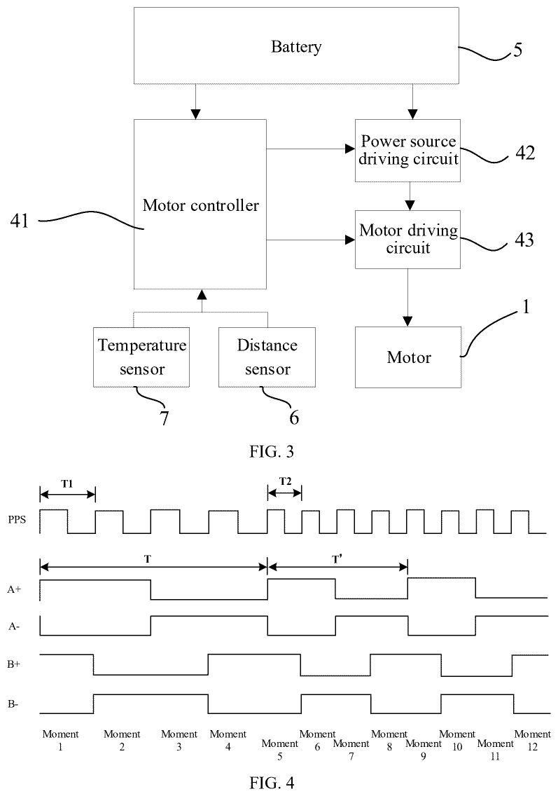

FIG. 3 is a schematic diagram of connections between related devices in a display apparatus according to some embodiments of the present disclosure. The control device 4 may be located on an SOC mainboard of the display apparatus. As shown in FIG. 3, the power device 10 may include a motor 1, and the motor 1 may be a stepping motor. It should be understood that the number of the motor 1 may be one or more. For example, the power device 10 may include a single motor 1 or may include two motors 1, and the motor controller 41 may use the same control method to control the operations of the two motors. The control device 4 may include a motor controller 41 and a motor driving circuit 43, the motor driving circuit 43 is connected to the motor 1, the motor driving circuit 43 may output a driving signal to the motor 1 in response to a control signal output by the motor controller 41, and the motor controller 41 is connected to the motor driving circuit 43. The motor controller 41 may be used to: in the first movement stage, control the motor 1 to operate at a first rotation rate to drive the flexible display panel 8 connected to the push rod 3 to move; obtain an actual rotation rate of the motor 1 in real time; if the actual rotation rate of the motor 1 is less than the first rotation rate, control the motor driving circuit 43 to output a driving signal with an increased thrust to the motor 1, so that the rotation rate of the motor 1 matches with the first rotation rate; based on the driving signal, detect whether the flexible display panel 8 completes the first movement stage; and, if the flexible display panel 8 completes the first movement stage, control the motor 1 to operate at a second rotation rate, until the flexible display panel 8 completes the second movement stage, where the second rotation rate is greater than the first rotation rate.

As described above, the power device 10 operates at the first rate in the first movement stage, and operates at the second rate in the second movement stage. In a case that the power device includes the motor 1, it is equivalent to that the motor 1 operates at a rotation rate (i.e., the first rotation rate) matching with the first rate in the first movement stage, and the motor 1 10 operates at a rotation rate (i.e., the second rotation rate) matching with the second rate in the second movement stage.

For example, the driving signal of the motor driving circuit 43 to the motor 1 may be a pulse signal, that is, the motor driving circuit 43 drives the motor 1 to rotate by outputting a pulse signal. The motor driving circuit 43 may adjust the rotation rate of the motor 1 by adjusting the frequency of the pulse signal. Of course, in other embodiments, the display apparatus 100 may further drive the flexible display panel 8 to move through other power devices 10.

The sliding and curling of the flexible display panel 8 includes curling and stretching. Curling refers to that all or part of the flexible display panel 8 transitions from the tiled state to the curled state, and stretching refers to that the curled flexible display panel 8 transitions to the tiled state.

In the present disclosure, the thrust needed by the flexible display panel 8 in the first movement stage is greater than the thrust needed by the flexible display panel 8 in the second movement stage. By taking the sliding and curling movement mode that the flexible display panel 8 transitions from a completed curled state to the tiled state as an example, in the first movement stage, since the flexible display panel 8 is completely curled, a larger thrust is needed to push the flexible display panel 8; and in the second movement stage, since part of the flexible display panel 8 has been pushed to the tiled state, comparatively, the thrust needed to push the remaining flexible display panel 8 in the curled state is correspondingly reduced. It can be known that when the output power of the motor is constant, the thrust of the motor is inversely proportional to the rotation rate of the motor; that is, the larger the rotation rate of the motor, the smaller the thrust of the motor; otherwise, the smaller the rotation rate of the motor, the larger the thrust of the motor. In the present disclosure, the motor 1 is controlled to operate at a relatively lower first rotation rate in the first movement stage, so that the motor has a larger thrust; and the motor 1 is controlled to operate at a higher second rotation rate in the second movement stage to reduce the thrust of the motor. That is, the rotation rate of the motor 1 is controlled according to different stages based on the movement stroke of the flexible display panel 8, so that the thrust of the motor 1 matches with the thrust needed by the movement stroke of the flexible display panel 8, thus solving the problem of insufficient thrust of the motor 1 caused by uneven thrust distribution in the moving process.

In some embodiments, a ratio of the first rotation rate to the second rotation rate may be greater than or equal to 0.5 and less than 1, for example, may be 0.5, 0.6, 0.7, 0.8, 0.9, 0.95, etc., so that the movement duration for the second movement stage may be reduced, thus the overall movement duration of the display apparatus 100 is equivalent to the movement duration of the movement using a uniform rate, which satisfies the display requirement. It should be understood that, in the present disclosure, the second rotation rate may be determined firstly, and then the first rotation rate may be determined according to the second rotation rate. That is, the rotation rate in the first movement stage may be correspondingly set according to the rotation rate in the second movement stage, so as to increase the thrust of the motor in a targeted manner. For example, in some embodiments, the first rotation rate is set to 0.5 times of the second rotation rate, so that the thrust of the motor may be increased by 15%-25%. Certainly, the proportional relationship between the first rotation rate and the second rotation rate should be set according to the specific structure of the display apparatus.

In addition, in the present disclosure, the display apparatus may be provided with a distance sensor 6. The movement distance of the flexible display panel 8 may be detected by the distance sensor 6. The movement distance of the flexible display panel 8 is the active displacement of the motor 1, so that the rotation rate of the motor 1 may be detected through the distance indication signal output by the distance sensor 6. For the specific principle of detecting the rotation rate of the motor 1 by the distance sensor 6, reference may be made to the description of the subsequent embodiments, and details are not described here again. Certainly, in other embodiments of the present disclosure, the rotation rate of the motor 1 may be detected in other manners; for example, the rotation rate may be detected by the Hall sensor provided in the motor 1. The specific detection method for the rotation rate of the motor 1 is not specifically limited in the present disclosure.

It should be understood that, in the present disclosure, the rotation rate of the motor 1 matching with the first rotation rate, may be understood as that the actual rotation rate of the motor 1 is the same as the first rotation rate, or the rotation rate difference between the actual rotation rate of the motor 1 and the first rotation rate is within a set threshold range.

As shown in FIG. 3, in some embodiments, the control device 4 may further include a power source driving circuit 42, the power source driving circuit 42 is connected to the motor controller 41 and the motor driving circuit 43 respectively, and the power source driving circuit 42 may output a corresponding voltage signal to the motor driving circuit 43 in response to a power control signal SWIRE of the motor controller 41. Among them, the control signal output by the motor controller 41 may include a rotation rate control signal IO and a power control signal SWIRE. The rotation rate control signal IO is output to the motor driving circuit 43, and the rotation rate control signal IO is used for controlling the motor driving circuit 43 to output a driving signal of a corresponding frequency. The power control signal SWIRE is output to the power source driving circuit 42, the power source driving circuit 42 may output a voltage signal of a certain magnitude to the motor driving circuit 43 in response to the power control signal SWIRE, and the motor driving circuit 43 adjusts the amplitude of the driving signal in response to the voltage signal to output a driving signal of a corresponding amplitude.

For example, both the power control signal SWIRE and the rotation rate control signal IO in the present disclosure include periodic pulse signals. The motor controller 41 may adjust the power of the motor 1 by adjusting the pulse number of the power control signal SWIRE and adjust the rotation rate of the motor 1 by adjusting the frequency of the rotation rate control signal IO. The motor driving circuit 43 generates a corresponding pulse signal (i.e., a driving signal) according to the voltage signal output by the power source driving circuit 42 and the rotation rate control signal IO output by the motor controller 41. In other words, the voltage magnitude of the driving signal output by the motor driving circuit 43 is determined by the power control signal SWIRE, and the frequency of the driving signal is determined by the rotation rate control signal IO. In actual operation, the motor controller 41 may adjust the power control signal SWIRE and the rotation rate control signal IO at the same time; that is, the power and the rotation rate of the motor 1 are adjusted at the same time. Alternatively, the rotation rate control signal IO or the power control signal SWIRE may be adjusted separately. That is, only the rotation rate of the motor 1 is adjusted, and the power of the motor 1 is kept unchanged; or, only the power of the motor 1 is adjusted, and the rotation rate of the motor 1 is kept constant. In some embodiments, the motor controller 41 may adjust the thrust of the motor 1 by preferentially adjusting the rotation rate of the motor 1; that is, the motor controller 41 preferentially adjusts the frequency of the rotation rate control signal IO.

For example, FIG. 4 is a schematic diagram of a correspondence between a frequency of the driving signal and a rotation rate control signal according to some embodiments of the present disclosure. By taking a 2-phase 4-wire motor as an example, A+, A−, B+, and B− represent driving signals, and PPS represents the frequency of a single pulse signal in the driving signal. In the stage from moment 1 to moment 4, PPS=1/T1; that is, at moment 1, moment 2, moment 3 and moment 4, there is each included a pulse signal of a period of T1. The stage from moment 1 to moment 4 may correspond to the first movement stage. In the stage from moment 5 to moment 12, PPS=1/T2; that is, at moment 5, moment 6, moment 7 and moment 8, moment 9, moment 10, moment 11, and moment 12, there is each included a pulse signal of a period of T2. The stage from moment 5 to moment 12 may correspond to the second movement stage. The rate of the motor 1 may be changed by changing the waveform period of the rotation rate control signal IO. As shown in FIG. 4, in the figure, in the stage from moment 1 to moment 4, the motor controller 41 outputs a rotation rate control signal IO of a first frequency, the rotation rate control signal IO of the first frequency is used to control that the waveform period of the driving signal outputted by the motor driving circuit 43 is T, and T=4*T1 based on the driving principle of the 2-phase 4-wire stepping motor. In the stage from moment 5 to moment 12, the motor controller 41 outputs a rotation rate control signal IO of a second frequency, the rotation rate control signal IO of the second frequency is used to control that the waveform period of the driving signal output by the motor driving circuit 43 is T′ (in the figure, moment 5 to moment 8 is one waveform period T′ of the driving signal), and based on the driving principle of the 2-phase 4-wire stepping motor, T′=4*T2, and T>T′. It can be seen that in the first movement stage, the motor controller 41 may reduce the frequency of the rotation rate control signal IO to control the motor driving circuit 43 to reduce the frequency of the driving signal, thus reducing the rotation rate of the motor 1 and further increasing the driving force of the motor 1. In the second movement stage, the motor controller 41 may increase the frequency of the rotation rate control signal IO to control the motor driving circuit 43 to increase the frequency of the driving signal, thus improving the rotation rate of the motor 1 and further reducing the duration of the second movement stage, so as to control the whole movement duration to match with the set duration. In some optional embodiments of the present disclosure, the waveform period T′ of the driving signal in the second movement stage may be set to ½ of the period T of the driving signal in the first movement stage; that is, the frequency of the driving signal in the second movement stage is twice the frequency of the driving signal in the first movement stage, as shown in FIG. 4, which is equivalent to that moment 9 to moment 12 is also exactly one complete driving signal period T′. In other words, from the moment 5 to moment 12 in FIG. 4, there is included driving signals of two complete periods. According to the correspondence between the rotation rate and the frequency of the driving signal of the motor, the motor may be controlled to drive the flexible display panel to move in the second movement stage at a rotation rate twice of the rotation rate in the first movement stage. It should be understood that the above are merely exemplary descriptions, and should not be construed as limiting of the relationship between the driving signals in the two movement stages of the present disclosure.

For example, FIG. 5 is a schematic diagram of a correspondence between an amplitude of a driving signal and a power control signal according to some embodiments of the present disclosure. By also taking a 2-phase 4-wire motor as an example, in the figure, A+, A−, B+, and B− represent driving signals, PPS represents a frequency of a single pulse signal in the driving signals, and PPS=1/T0. In the stage from moment 1 to moment 8, for each moment stage, there is included a pulse signal of a period of T0. In the stage from moment 1 to moment 4, the power control signal SWIRE output by the motor controller 41 is used to control the power source driving circuit 42 to output a first voltage, and the first voltage is used to control that the voltage magnitude of the driving signal output by the motor driving circuit 43 is V. In the stage from moment 5 to moment 12, the power control signal SWIRE output by the motor controller 41 is used to control the power source driving circuit 42 to output a second voltage, the second voltage is used to control that the voltage magnitude of the driving signal output by the motor driving circuit 43 is V′, and V>V′. Obviously, the power of the driving signal in the stage from moment 1 to moment 4 is greater than the power of the driving signal in the stage from moment 5 to moment 12. For example, the stage from moment 1 to moment 4 may correspond to the first movement stage. For example, the stage from moment 5 to moment 12 may correspond to the second movement stage.

The relationship between the thrust of the motor and the power of the motor is as shown in formula (2).

$$F = \frac{k * π * W * η}{P * A * L} * I \qquad ( 2 )$$

In the above formula, P represents the driving frequency of the motor; A represents the pitch angle of the motor, the unit of which is °; I represents the gear ratio (a constant); L represents the lead of the push rod, the unit of which is mm; V represents the sliding rate, the unit of which is mm/s; η represents the transmission efficiency (a constant); W represents the power, the unit of which is w; F represents the motor thrust, the unit of which is g; and k is the coefficient calculated according to the torque.

It can be seen from formula (2) that the thrust of the motor is proportional to the power. Therefore, in the driving mode shown in FIG. 5, the thrust of the motor driving circuit 43 in the stage from moment 1 to moment 4 (i.e., the first movement stage) is greater than the thrust in the stage from moment 5 to moment 12 (i.e., the second movement stage). That is, the power control signal SWIRE may be used to improve the thrust of the motor 1 in the first movement stage by increasing the signal amplitude of the driving signal in the first movement stage. In the second movement stage, the power control signal SWIRE may be used to control the output power of the motor driving circuit 43 to be reduced by reducing the signal amplitude of the driving signal, so as to reduce the thrust of the motor. In addition, since the amplitude of the driving signal in the second movement stage is reduced, the motor does not operate in an overloaded manner. The service life of the motor is shortened when the motor operates in an overloaded manner for a long time. Therefore, by reducing the amplitude of the driving signal in the second movement stage, long-time overloaded operation of the motor may be avoided, so that the service life of the motor may be effectively guaranteed. In some embodiments of the present disclosure, the ratio of the amplitude V of the driving signal in the first movement stage to the amplitude V′ of the driving signal in the second movement stage may be greater than 1 and less than or equal to 1.2; for example, it may be 1.05, 1.1, 1.15, 1.2, etc., so that the amplitude of the driving signal in the first movement stage may be correspondingly adjusted according to the amplitude of the driving signal in the second movement stage, thus increasing the thrust of the motor in the first movement stage.

As shown in FIG. 1 to FIG. 3, in some embodiments, the display apparatus 100 may further include a temperature sensor 7, the temperature sensor 7 is connected to the motor controller 41, and the temperature sensor 7 may be used to detect an ambient temperature of the display apparatus 100 and output a temperature indication signal to the motor controller 41. Correspondingly, the motor controller 41 may perform parsing on the temperature indication signal to obtain the current temperature of the display apparatus 100, and may compare the current temperature with a preset temperature threshold. If the current temperature is less than or equal to the temperature threshold, the motor controller 41 may output a rotation rate control signal IO with a reduced frequency and/or output a power control signal SWIRE with an increased pulse number. The power source driving circuit 42 may output a voltage signal with an increased amplitude in response to the power control signal SWIRE with an increased pulse number. Correspondingly, the motor driving circuit 43 may determine the adjusted frequency of the driving signal in response to the rotation rate control signal IO with the reduced frequency and/or determine the adjusted amplitude of the driving signal in response to the voltage signal with the increased amplitude, and output the adjusted driving signal. The rotation rate control signal IO with the reduced frequency may reduce the frequency of the driving signal, so as to reduce the rotation rate of the motor 1 and improve the thrust of the motor 1; and the voltage signal with the increased amplitude may increase the voltage amplitude of the driving signal, so as to improve the power of the motor 1 and improve the thrust of the motor 1.

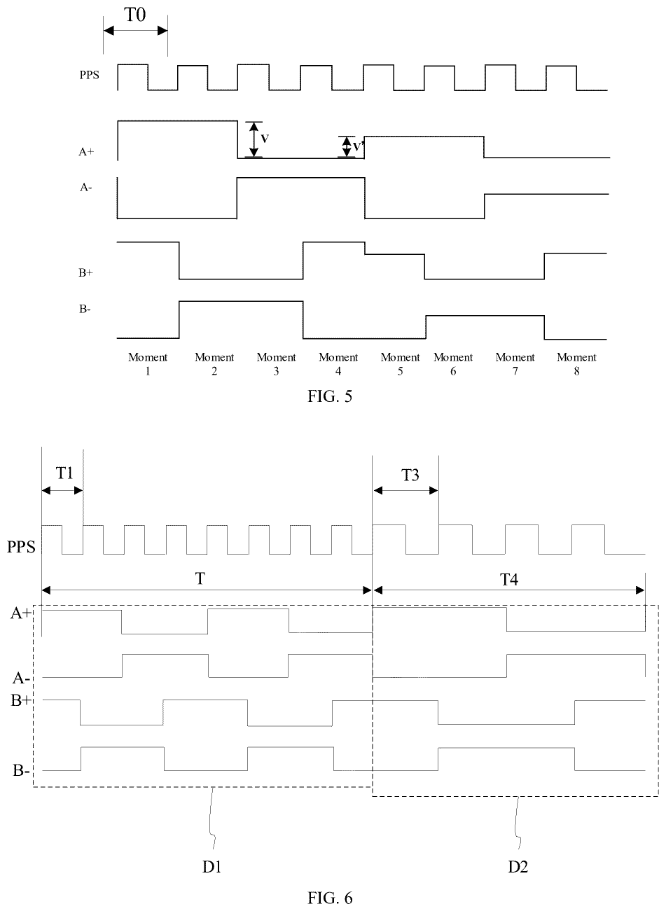

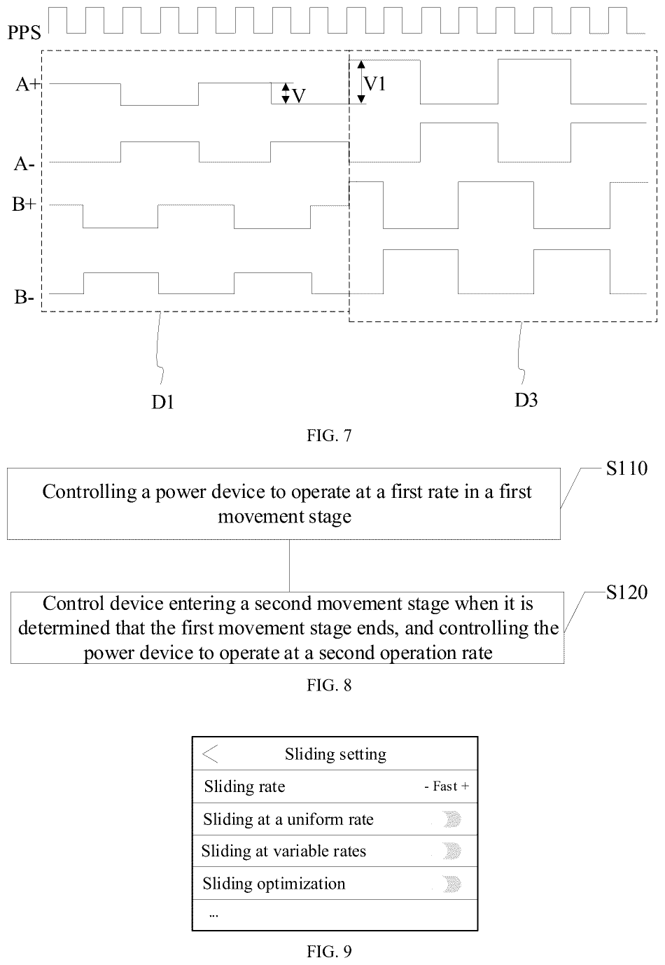

For example, FIG. 6 is a schematic diagram of adjustment of a rotation rate control signal according to some embodiments of the present disclosure. In the figure, A+, A−, B+, B− represent driving signals, PPS represents a frequency of a single pulse signal in the driving signal, T1 represents a signal period of a single pulse signal in the driving signal in the first movement stage, T3 represents a signal period of a single pulse signal in the adjusted driving signal, T represents a signal period of the driving signal in the first movement stage, and T4 represents a signal period of the adjusted driving signal. FIG. 7 is a schematic diagram of adjustment of a power control signal according to some embodiments of the present disclosure. In the figure, A+, A−, B+, and B− represent driving signals, PPS represents a frequency of a single pulse signal in the driving signal, V represents a signal amplitude of the driving signal in the first movement stage, and V1 represents a signal amplitude of the adjusted driving signal. When the motor controller 41 determines that the current temperature is less than or equal to the temperature threshold by performing parsing on the temperature indication signal, the motor controller 41 may control the driving signal to be changed from the first driving signal D1 to the second driving signal D2 by adjusting the rotation rate control signal IO, as shown in FIG. 6, so as to reduce the frequency of the driving signal, thus reducing the rotation rate of the motor and improving the thrust of the motor. Alternatively, the motor controller 41 may adjust the voltage magnitude of the driving signal to make the driving signal changed from the first driving signal D1 to the third driving signal D3 by adjusting the power control signal SWIRE, as shown in FIG. 7, so as to increase the voltage amplitude of the driving signal, thus improving the power of the motor and improving the thrust of the motor.

It may be understood that the temperature sensor 7 detects the ambient temperature of the display apparatus 100 in real time and feeds back a temperature indication signal to the motor controller 41 in real time. Correspondingly, the motor controller 41 may obtain the real-time ambient temperature. When the motor controller 41 determines that the current ambient temperature is greater than the temperature threshold, that is, the display apparatus 100 is no longer in a low-temperature operation state, the motor controller 41 may reduce the thrust of the motor 1. For example, at a certain moment, the ambient temperature of the display apparatus 100 is greater than the temperature threshold, and the motor controller 41 may output a rotation rate control signal IO matching with the first movement stage to the motor driving circuit 43 to control the motor 1 to operate at the first rotation rate, and/or output a power control signal SWIRE matching with the first movement stage to the power source driving circuit 42 to control the motor 1 to operate according to the power in the previous stage of sliding and curling stroke. Through adjusting the rotation rate control signal IO and/or the power control signal SWIRE in real time by the motor controller 41, it may avoid affecting the service life of the motor 1 due to long-time overloaded operation of the motor 1.

As shown in FIG. 1 to FIG. 3, in some embodiments, the display apparatus 100 may further include a distance sensor 6, and the distance sensor 6 may be, for example, a PCR millimeter wave radar sensor. The distance sensor 6 is connected to the motor controller 41. The distance sensor 6 may include a transmitting end 61 and a receiving end 62, the transmitting end 61 may be provided at a fixed end of the flexible display panel 8, and the receiving end 62 may be located at a movable end of the flexible display panel. The distance sensor 6 may detect a distance between the fixed end and the movable end of the flexible display panel 8 in real time, and output a distance indication signal to the motor controller 41. Correspondingly, the motor controller 41 may perform parsing on the distance indication signal to determine the movement distance of the flexible display panel 8, and determine the current rotation rate of the motor 1 based on the movement distance and a movement duration. The motor controller 41 further compares the current rotation rate of the motor 1 with the first rotation rate; and if the current rotation rate is less than the first rotation rate, the motor controller 41 may output a rotation rate control signal with a reduced frequency to the motor driving circuit 43 and/or output a power control signal with an increased pulse number to the power source driving circuit 42. Correspondingly, the power source driving circuit 42 may output a voltage signal with an increased amplitude in response to the power control signal with an increased pulse number. The motor driving circuit 43 may determine the frequency of the adjusted driving signal in response to the rotation rate control signal with a reduced frequency and/or determine the amplitude of the adjusted driving signal in response to the voltage signal with the increased amplitude, and output the adjusted driving signal as shown in FIG. 6 or the adjusted driving signal as shown in FIG. 7. As described above, the rotation rate control signal with a reduced frequency may reduce the frequency of the driving signal, so as to reduce the rotation rate of the motor 1 and improve the thrust of the motor 1. The power control signal with an increased pulse number may increase the amplitude of the voltage signal to increase the power of the driving signal, so as to improve the power of the motor 1 and improve the thrust of the motor 1. Therefore, in the first movement stage, the actual rotation rate of the motor 1 matches with the first rotation rate of the stroke stage.

It can be understood that the rotation rate adjustment of the motor controller 41 to the motor 1 is a dynamic adjustment process. When the motor controller 41 determines, by using the distance indication signal, that the current rotation rate of the motor 1 matches with the first rotation rate, the motor controller 41 no longer reduces the frequency of the rotation rate control signal IO and/or no longer increases the pulse number of the power control signal SWIRE. That is, the motor 1 is controlled to maintain the current rotation rate and/or power to operate.

The present disclosure further provides a method for display panel movement control. FIG. 8 is a flowchart of a method for display panel movement control according to some embodiments of the present disclosure. The method may be performed by a control device, and the control device may be, for example, a motor controller. By running this control method, the power of the power device can be reasonably allocated according to the movement stroke of the flexible display panel, avoiding the problem of insufficient driving force. As shown in FIG. 8, the control method may include the following steps.

In S110, a power device is controlled to operate at a first rate in a first movement stage.

In S120, the power device is controlled to operate at a second rate in the second movement stage, where the second rate is greater than the first rate.

According to the method for display panel movement control provided by the present disclosure, in the first movement stage, the power device operates at the first rate; and in the second movement stage, the power device operates at the second rate, where the second rate is greater than the first rate. By controlling the driving force of the power device according to different stages, the problem of insufficient thrust in the movement process can be solved without additionally adding a power device, i.e., without increasing the cost.

The above steps of the example embodiment will be described in more detail below.

In step S110, the power device is controlled to operate at the first rate in the first movement stage.

In some embodiments, the power device may be a motor, and may be specifically a stepping motor. The control device may include a motor controller, a motor driving circuit, and a power source driving circuit. The motor controller may output a rotation rate control signal IO to the motor driving circuit and output a power control signal SWIRE to the power source driving circuit. The power source driving circuit further outputs a voltage signal of a certain magnitude to the motor driving circuit according to the power control signal SWIRE. The motor driving circuit determines the frequency of the driving signal to be output according to the rotation rate control signal IO and determines the amplitude of the driving signal to be output according to the voltage signal.

Therefore, step S110 is as follows: the motor is controlled to operate at a first rotation rate in the first movement stage to drive the flexible display panel connected to a push rod to move.

Among them, the first rotation rate of the motor corresponds to the first rate of the power device in the first movement stage.

For example, the following formula (1) shows a relationship between the rotation rate and the frequency of the motor.

$$V = \frac{\frac{P * A}{360}}{I} * L \qquad ( 1 )$$

In the above formula, P represents the driving frequency of the motor; A represents the pitch angle of the motor, the unit of which is °; I represents the transmission ratio (a constant); L represents the lead of the push rod, the unit of which is mm; and V represents the sliding rate, the unit of which is mm/s.

It can be seen from formula (1) that the rotation rate of the motor may be controlled through the frequency of the rotation rate control signal IO; that is, the motor driving circuit may be enabled to drive the motor to rotate at the first rotation rate by setting the frequency of the rotation rate control signal IO. For example, the correspondence between the frequency of the rotation rate control signal IO and the rotation rate of the motor may be pre-stored in the motor controller, and the motor controller may output the rotation rate control signal IO of the first frequency according to the correspondence to control the motor to rotate at the first rotation rate.

In some embodiments, before step S110, the control method may further include the following steps.

In S101, a temperature indication signal output by a temperature sensor is obtained.

In S102, a current temperature is determined based on the temperature indication signal.

In S103, if the current temperature is less than a preset temperature threshold, the motor driving circuit is controlled to output a driving signal for increasing the driving force to the motor, to cause the actual rotation rate of the motor to match with the first rotation rate.

For example, the display apparatus may include a temperature sensor, the temperature sensor is connected to the motor controller, and the temperature sensor may sense an ambient temperature of the motor in real time and output a temperature indication signal to the motor controller based on the sensed temperature. Correspondingly, the motor controller may perform parsing the temperature indication signal to obtain the current temperature, and compare the current temperature with a set temperature threshold. When the current temperature is determined to be lower the temperature threshold, it indicates that the display apparatus is currently operating at a low temperature. The motor controller may control the motor driving circuit to output a driving signal for increasing the thrust, so as to improve the thrust of the motor, thus matching with the requirement of a high thrust of the display apparatus in a low temperature environment.

For example, the motor controller may output a rotation rate control signal with a reduced frequency as shown in FIG. 6 to the motor driving circuit and/or output a power control signal with an increased pulse number as shown in FIG. 7 to the power source driving circuit. The power control signal with an increased pulse number is used to instruct the motor driving circuit to output a rotation rate control signal with an increased amplitude, so as to improve the power of the motor and improve the thrust of the motor. The specific principles of using a rotation rate control signal with a reduced frequency and a power control signal with an increased pulse number to improve the thrust may refer to the introduction of the above embodiments, which will not be repeated here.

In step S120, the control device enters the second movement stage when it is determined that the first movement stage ends, and controls the power device to operate at a second operation rate.

Taking the power device being a motor as an example, step S120 is as follows: when detecting that the flexible display panel completes the first movement stage, the motor controller controls the motor to operate at the second rotation rate, where the second rotation rate is greater than the first rotation rate.

Among them, the second rotation rate corresponds to the second rate of the power device in the second movement stage.

In some embodiments, the motor controller may modify the timer interruption period or the thread sleep time to output a rotation rate control signal of a second frequency to control the motor to rotate at the second rotation rate in the second movement stage. The second rotation rate is greater than the first rotation rate, so that the movement duration of the motor in the second movement stage may be shortened, thus ensuring that the movement duration of the whole moving process does not exceed the set duration, and meeting the display requirement.

In some embodiments, before step S120, the control method may further include the following steps.

In S130, it is detected whether the flexible display panel completes the first movement stage.

Taking the power device being a motor as an example, step S130 is as following: the motor controller detects, based on the driving signal, whether the flexible display panel completes the first movement stage.

Among them, the driving signal includes a periodic pulse signal. Taking the stepping motor as an example, when the stepping motor obtains a pulse signal, the stepping motor moves for a unit displacement. Therefore, the displacement of the motor may be determined according to the pulse number of the driving signal, so as to determine whether the flexible display panel currently completes the first movement stage.

The motor controller may adjust the pulse period of the rotation rate control signal by modifying the timer interruption period or the thread sleep time. Assuming that the total movement stroke is S, the frequency of the driving signal in the first movement stage H is M, and the frequency of the driving signal in the second movement stage (S-H) is M′. According to the motor rate V and the frequency of the driving signal, the motor controller may calculate the number Q of pulses needed for the motor to run the H stroke according to the following formula (3).

$$Q = \frac{H * M}{V} \qquad ( 3 )$$

In the above formula, Q represents the pulse number, H represents the first movement stage, M represents the frequency of the driving signal in the first movement stage, and V represents the rotation rate of the motor in the first movement stage.

The motor controller sends a rotation rate control signal while counting the pulse number of the driving signal cumulatively. When the cumulative pulse number is equal to Q, it indicates that the flexible display panel has completed the stroke of the first movement stage.

In some embodiments, step S130 may specifically include the following steps.

In S131, the pulse number of the rotation rate control signal output cumulatively by the motor driving circuit is calculated.

In S132, a rotation displacement of the motor is determined based on the pulse number and the rotation rate of the motor.

In S133, the rotation displacement of the motor is compared with a distance value of the first movement stage.

In S134, if the rotation displacement of the motor is equal to the distance value of the first movement stage, it is determined that the flexible display panel completes the first movement stage; or

In S135, if the rotation displacement of the motor is less than the distance value of the first movement stage, it is determined that the flexible display panel is in the first movement stage. Among them, there is a correspondence between the frequency of the rotation rate control signal and the frequency of the driving signal, so that the motor controller may obtain the pulse number of the driving signal by counting the pulse number of the output rotation rate control signal cumulatively, and then calculate the rotation displacement of the motor in combination with the rotation rate of the motor. It can be known that the rotation displacement of the motor is the movement displacement of the flexible display panel, and the distance value of the first movement stage is predetermined. Therefore, whether the flexible display panel completes the first movement stage may be detected by comparing the rotation displacement of the motor with the distance value of the first movement stage.

After detecting that the flexible display panel completes the first movement stage, the motor controller controls the motor to rotate at the higher second rotation rate, so as to reduce the movement duration in the second movement stage, thus ensuring that the duration of the whole moving process is within a set duration range, and meeting the display requirement.

In some embodiments, before step S130, the control method may further include the following steps.

In S111, an actual rotation rate of the motor is obtained in real time.

In S112, if the actual rotation rate of the motor is less than the first rotation rate, the motor driving circuit is controlled to output a driving signal for increasing the driving force to the motor, so that the rotation rate of the motor matches with the first rotation rate.

Among them, the display apparatus may include a distance sensor. The distance sensor may be used to detect a distance between the fixed end and the movable end of the flexible display panel, and output a distance indication signal to the motor controller. The motor controller obtains a movement distance of the flexible display panel by performing parsing on the distance indication signal, and determines the actual rotation rate of the motor based on the movement distance. For example, step S111 may specifically include the following steps.

In S1111, a distance indication signal output by the distance sensor is obtained in real time.

In S1112, a movement distance of the flexible display panel is determined based on the distance indication signal.

In S1113, the actual rotation rate of the motor is determined based on the movement distance and the movement duration.

Among them, the motor controller obtains the movement distance of the flexible display panel by performing parsing on the distance indication signal. It can be understood that the movement distance of the flexible display panel is the rotation displacement of the motor within the time, and the motor controller may obtain the actual rotation rate of the motor by calculating in combination with the movement duration.

After determining the actual rotation rate of the motor, in step S112, the motor controller further detects the thrust of the motor according to the actual rotation rate of the motor. In some embodiments, the relationship between the thrust of the motor and the rotation rate of the motor as well as the power of the motor is as shown in formula (2).

$$F = \frac{k * π * W * η}{P * A * L} * I \qquad ( 2 )$$

In the above formula, P represents the driving frequency of the motor; A represents the pitch angle of the motor, the unit of which is °; I represents the gear ratio (a constant); L represents the lead of the push rod, the unit of which is mm; V represents the sliding rate, the unit of which is mm/s; η represents the transmission efficiency (a constant); W represents the power, the unit of which is w; F represents the motor thrust, the unit of which is g; and k is the coefficient calculated according to the torque.

It can be seen from formula (2) that the thrust of the motor is inversely proportional to the frequency of the driving signal, and is proportional to the power. Therefore, on one hand, the motor controller may detect whether the thrust of the motor is insufficient based on the current rotation rate of the motor. On the other hand, when it is detected that the thrust of the motor is insufficient, the thrust of the motor may be improved by reducing the frequency of the driving signal and/or increasing the power of the driving signal.

For example, step S112 may specifically include follows. If the actual rotation rate of the motor is less than the first rotation rate, a first rotation rate control signal with a reduced frequency is output to the motor driving circuit, and/or a power control signal with an increased pulse number is output to the power source driving circuit. The power control signal is used to instruct the motor driving circuit to output a rotation rate control signal with an increased amplitude, so that the rotation rate of the motor matches with the first rotation rate.

It can be learned from the foregoing analysis that, if the actual rotation rate of the motor is less than the first rotation rate, it indicates that the current thrust of the motor is insufficient, and the thrust of the motor needs to be improved.

As described above, both the power control signal and the rotation rate control signal include periodic pulse signals. The power source driving circuit may determine the magnitude of the voltage signal output to the motor driving circuit according to the pulse number of the power control signal, to adjust the voltage magnitude of the driving signal output by the motor driving circuit; and/or, the motor controller may output a rotation rate control signal with a reduced frequency, and the motor driving circuit may determine the frequency of the driving signal to be output after adjustment according to the pulse frequency of the rotation rate control signal.

It may be understood that, in this step, the motor controller may adjust the power control signal and the rotation rate control signal at the same time, or may only adjust the rotation rate control signal or only adjust the power control signal. In a preferred embodiment of the present disclosure, the motor controller may preferentially adjust the frequency of the rotation rate control signal, that is, reducing the frequency of the rotation rate control signal to reduce the rotation rate of the motor, thus improving the thrust of the motor, so that the overloaded operation of the motor may be avoided, and the service life of the motor is not affected.

In addition, it should be noted that, in the present disclosure, the pulse number of the power control signal may be limited in the motor controller to limit the maximum voltage value that can be determined by the power source driving circuit, thus avoiding that the motor is burned down due to the voltage value of the driving signal exceeding the maximum withstand voltage of the motor.

In addition, it should be understood that the motor controller further needs to combine the distance indication signal of the distance sensor to detect the current rotation rate of the motor in real time. After adjustment of the power control signal and/or the rotation rate control signal and detecting that the current rotation rate of the motor has matched with the first rotation rate of the current stroke, the motor controller no longer adjusts the power control signal and/or the rotation rate control signal.

It may be understood that, in the second movement stage, the motor controller may also detect the motor thrust in real time according to the distance sensor, and improve the thrust of the motor according to the control method in the first movement stage when it is detected that the thrust of the motor is insufficient. In addition, the motor controller may further detect the ambient temperature of the display apparatus in the second movement stage in real time according to the temperature sensor, and improve the thrust of the motor when it is detected that the ambient temperature is lower than the temperature threshold.

The present disclosure may provide a user interface for the display apparatus, for the user to select a corresponding movement manner of the flexible display panel according to use requirements. For example, FIG. 9 is a sliding setting interface of the display apparatus provided according to some embodiments of the present disclosure. As shown in FIG. 9, when the user selects sliding at a uniform rate, the motor drives the flexible display panel to perform sliding and curling at a constant rate; and when this option is not selected, the user may set the sliding rate as needed. In addition, as shown in FIG. 9, the user selection interface may further provide options of sliding at variable rates and sliding optimization; and when the user selects the option of sliding at variable rates, the motor controller in the display apparatus may perform the control method shown in steps S110 to S130, to control the motor to drive the flexible display panel to perform sliding and curling at different rotation rates in different stages. When the user selects the option of sliding optimization, the motor controller in the display apparatus may perform steps S111 to S112, and automatically detect the actual rotation rate of the motor according to the distance sensor and compare the actual rotation rate with the set rotation rate to determine whether the frequency and/or amplitude of the motor need to be adjusted, so as to optimize the control of the sliding and curling of the flexible display panel.

In conclusion, according to the method for display panel movement control in the present disclosure, during normal start, the motor controller controls the motor to rotate at the first rotation rate, and the motor controller simultaneously detects whether the display apparatus is operating at a low temperature according to the temperature indication signal of the temperature sensor. When it is detected that the display apparatus is operating at a low temperature, the motor controller controls the motor to improve the thrust to match with the thrust requirement during the low-temperature operation. Meanwhile, the motor controller may detect the rotation rate of the motor in real time according to the distance sensor, detect whether the thrust of the motor is insufficient according to the rotation rate, and further control the motor to improve the thrust when it is detected that the thrust of the motor is insufficient. After the first movement stage is completed, the motor controller controls the motor to increase the rotation rate in the second movement stage to reduce the movement duration in the second movement stage, thus ensuring that the movement duration of the whole moving process meets the requirement. According to the control method of the present disclosure, the number of motors does not need to be increased. The rotation rate of the motor is controlled according to different stages, the running state of the motor is adjusted in real time in combination with the output signals of the temperature sensor and the distance sensor, and it is ensured that the flexible display panel of the display apparatus can move normally.

The present disclosure further provides an apparatus 400 for display panel movement control.

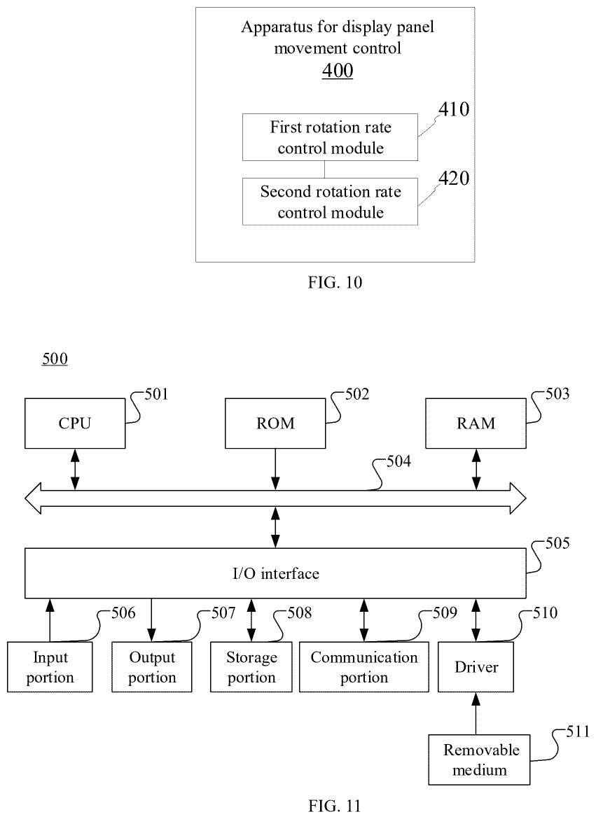

FIG. 10 is a structural block diagram of an apparatus for display panel movement control according to some embodiments of the present disclosure. As shown in FIG. 10, the apparatus may include a first rotation rate control module 410 and a second rotation rate control module 420.

The first rotation rate control module 410 may be used to control the power device to operate at a first rate in a first movement stage.

The second rotation rate control module 420 may be used to control the power device to operate at a second rate, where the second rate is greater than the first rate.

In some embodiments, the first rotation rate control module 410 may be further used to control the motor to operate at the first rotation rate in the first movement stage.

In some embodiments, the apparatus may further include a determination module 430, and the determination module 430 may be used to detect, based on the output driving signal, whether the flexible display panel completes the first movement stage.

In some embodiments, the determination module 430 may be further used to detect whether the flexible display panel completes the first movement stage based on the driving signal.

The second rotation rate control module 420 may be further used to, if the flexible display panel completes the first movement stage, control the motor to operate at the second rotation rate until the flexible display panel completes the second movement stage, where the second rotation rate is greater than the first rotation rate.

In some embodiments, the apparatus may further include a rotation rate obtaining module and a control module.

The rotation rate obtaining module may be used to obtain an actual rotation rate of the motor in real time.

The control module may be used to, if the actual rotation rate of the motor is less than the first rotation rate, control the motor driving circuit to output a driving signal for increasing the driving force to the motor, so that the rotation rate of the motor matches with the first rotation rate.

In some embodiments, the rotation rate obtaining module may be further used to determine a movement distance of the flexible display panel based on the distance indication signal, and determine an actual rotation rate of the motor based on the movement distance and the movement duration. Among them, the distance indication signal may be output by a distance sensor in the display apparatus, and the distance sensor may be specifically used to detect a distance between the fixed end and the movable end of the flexible display panel.

In some embodiments, the control device may further include a comparison module and a detection module.

The comparison module is used to compare the current rotation rate with the first rotation rate.

The detection module is used to determine that the actual rotation rate of the motor is less than the first rotation rate if the rotation rate difference between the current rotation rate and the first rotation rate is greater than or equal to a preset rotation rate threshold.

In some embodiments, the control module may be further used to: output a rotation rate control signal with a reduced pulse frequency to the motor driving circuit, and/or output a power control signal with an increased pulse number to the power source driving circuit, where the power control signal is used to instruct the motor driving circuit to output a driving signal with an increased amplitude. Among them, the power source driving circuit is connected to the motor controller and the motor driving circuit respectively, and the motor driving circuit is connected to the motor controller and the motor respectively.

In some embodiments, the control device may further include an accumulation module and a movement distance determination module.

The accumulation module is used to calculate the pulse number of the rotation rate control signal that is output cumulatively.

The movement distance determination module is used to determine a movement distance of the flexible display panel based on the pulse number and the rotation rate of the motor.

Correspondingly, the comparison module may be further used to compare the movement distance of the flexible display panel with the distance value of the first movement stage.

The determination module 430 may be further used to: if the movement distance of the flexible display panel is equal to the distance value of the first movement stage, determine that the flexible display panel completes the first movement stage; or, if the movement distance of the flexible display panel is less than the distance value of the first movement stage, determine that the flexible display panel is in the first movement stage.

In some embodiments, the first rotation rate control module 410 may be further used to control the motor driving circuit to output a rotation rate control signal of a first frequency to the motor, where the rotation rate control signal of the first frequency is used to instruct the motor driving circuit to drive the motor to rotate at the first rotation rate.

In some embodiments, the second rotation rate control module 420 may be further used to control the motor driving circuit to output a rotation rate control signal of a second frequency to the motor, where the second frequency is greater than the first frequency, and the rotation rate control signal of the second frequency is used to instruct the motor driving circuit to drive the motor to rotate at the second rotation rate.

In some embodiments, the apparatus may further include a temperature obtaining module and a temperature determination module.

The temperature obtaining module is used to obtain a temperature indication signal output by a temperature sensor.

The temperature determination module is used to determine a current temperature based on the temperature indication signal.

Correspondingly, the control module may be further used to, if the current temperature is less than the preset temperature threshold, control the motor driving circuit to output a driving signal for increasing the driving force to the motor, so that the actual rotation rate of the motor matches with the first rotation rate. Among them, the temperature indication signal may be output by the temperature sensor, and the temperature sensor may be specifically used to detect an ambient temperature of the display apparatus.

FIG. 11 is a schematic structural diagram of a control device according to some embodiments of the present disclosure. It should be noted that the control device 500 shown in FIG. 11 is merely an example, and should not bring any limitation to the function and scope of use of the embodiments of the present disclosure. As shown in FIG. 11, the control device 500 may include, but is not limited to, a motor controller, or the like.

As shown in FIG. 11, the control device 500 includes a central processing unit (CPU) 501, which may perform various appropriate actions and processes according to a program stored in a read-only memory (ROM) 502 or a program loaded into a random access memory (RAM) 503 from a storage portion 508. In (RAM) 503, various programs and data needed for system operations are also stored. (CPU) 501, (ROM) 502, and (RAM) 503 are connected to each other via a bus 504. An input/output (I/O) interface 505 is also connected to the bus 504.

The following components are connected to (I/O) interface 505: an input portion 506 including a keyboard, a mouse, etc.; an output portion 507 including a cathode ray tube (CRT), a liquid crystal display (LCD), and a speaker, etc.; a storage portion 508 including a hard disk; and a communication portion 509 including a network interface card such as a LAN card, a modem, etc. The communication portion 509 performs communication processing via a network such as the Internet. The driver 510 is also connected to the (I/O) interface 505 as needed. The removable medium 511, such as a magnetic disk, an optical disk, a magneto-optical disk, a semiconductor memory, etc., is mounted on the driver 510 as needed, so that the computer program read therefrom is installed into the storage portion 508 as needed.

In particular, according to embodiments of the present disclosure, the process described with reference to the flowchart 8 may be implemented as a computer software program. For example, an embodiment of the present disclosure includes a computer program product, which includes a computer program carried on a computer-readable storage medium, and the computer program includes program code for executing the method shown in the flowchart. In such an embodiment, the computer program may be downloaded and installed from the network through the communication portion 509, and/or installed from the removable medium 511. When the computer program is executed by the central processing unit (CPU) 501, various functions defined in the method and apparatus of the present disclosure are performed.

It should be noted that the computer-readable storage medium shown in the present disclosure may be a computer-readable signal medium or a computer-readable storage medium or any combination of the two. The computer-readable storage medium may be, for example, but is not limited to, an electronic, magnetic, optical, electromagnetic, infrared, or semiconductor system, apparatus, or device, or any combination of them. A more specific example of a computer-readable storage medium may include, but is not limited to, an electrical connection having one or more wires, a portable computer diskette, a hard disk, a random access memory (RAM), a read-only memory (ROM), an erasable programmable read-only memory (EPROM or flash memory), an optical fiber, a portable compact disk read-only memory (CD-ROM), an optical storage apparatus, a magnetic storage apparatus, or any suitable combination of the above. In the present disclosure, the computer-readable storage medium may be any tangible medium containing or storing a program, and the program may be used by or used in combination with an instruction execution system, apparatus, or device. In the present disclosure, the computer-readable signal medium may include a data signal propagated in a baseband or as part of a carrier, where the computer-readable program code is carried. Such a propagated data signal may take a variety of forms, including but not limited to an electromagnetic signal, an optical signal, or any suitable combination of the foregoing. The computer-readable signal medium may also be any computer-readable storage medium other than a computer-readable storage medium, and the computer-readable storage medium may send, propagate, or transmit a program for use by or in connection with an instruction execution system, apparatus, or device. The program code included in the computer-readable storage medium may be transmitted by using any suitable medium, including but not limited to: wireless, wire, optical cable, etc., or any suitable combination of the foregoing.

In another aspect, the present disclosure further provides a computer-readable storage medium, which may be included in the control device 500 described in the foregoing embodiments, or may exist alone without being assembled into the control device 500. The computer-readable storage medium carries one or more programs, and when the one or more programs are executed by one of the control devices 500, the control device 500 is enabled to implement the method in the following embodiments. For example, the control device 500 may implement various steps as shown in FIG. 8.

Other embodiments of the present disclosure will be apparent to those skilled in the art from consideration of the specification and practice of the present disclosure here. The present disclosure is intended to cover any variations, uses, or adaptations of the disclosure following the general principles thereof and including the common general knowledge and conventional technical means in the art not disclosed in the present disclosure. It is intended that the specification and examples are considered as exemplary only, with a true scope and spirit of the disclosure being indicated by the appended claims.

1. A display apparatus, comprising:
a flexible display panel;
a power device, connected to the flexible display panel, wherein the power device drives the flexible display panel to move in response to a driving signal; and
a control device, connected to the power device, wherein the control device is used to control the power device to operate at a first rate in a first movement stage of the flexible display panel, and control the power device to operate at a second rate in a second movement stage of the flexible display panel, and the second rate is greater than the first rate.

2. The display apparatus according to claim 1, further comprising:
a push rod, connected to the flexible display panel;
wherein the power device comprises a motor, and a power end of the motor is connected to the push rod to drive the flexible display panel through the push rod; and
the control device comprises:
a motor driving circuit, connected to the motor, wherein the motor driving circuit outputs a driving signal to the motor in response to a control signal; and
a motor controller, connected to the motor driving circuit, wherein the motor controller is used to: control, in the first movement stage, the motor to operate at a first rotation rate to drive the flexible display panel connected to the push rod to move; obtain an actual rotation rate of the motor in real time; in response to the actual rotation rate of the motor being less than the first rotation rate, control the motor driving circuit to output a driving signal for increasing a driving force to the motor, to cause a rotation rate of the motor to match with the first rotation rate; detect, based on the driving signal, whether the flexible display panel completes the first movement stage; and in response to the flexible display panel completing the first movement stage, control the motor to operate at a second rotation rate, until the flexible display panel completes a second movement stage, wherein the second rotation rate is greater than the first rotation rate.

3. The display apparatus according to claim 2, wherein the control signal comprises a rotation rate control signal and a power control signal, the rotation rate control signal is used for adjusting a frequency of the driving signal, and the power control signal is used for adjusting an amplitude of the driving signal;
the motor controller is used to output the rotation rate control signal and the power control signal;
the control device further comprises a power source driving circuit, the power source driving circuit is connected to the motor controller and the motor driving circuit respectively, and the power source driving circuit is used to output a corresponding voltage signal in response to the power control signal; and
the motor driving circuit is further used to determine the frequency of the driving signal in response to the rotation rate control signal, determine the amplitude of the driving signal in response to the voltage signal, and output a corresponding driving signal.

4. The display apparatus according to claim 3, further comprising:
a temperature sensor, connected to the motor controller, wherein the temperature sensor is used to detect an ambient temperature of the display apparatus and output a temperature indication signal to the motor controller;
wherein the motor controller is further used to:
determine a current temperature based on the temperature indication signal;
compare the current temperature with a preset temperature threshold; and
in response to the current temperature being less than or equal to the temperature threshold, output at least one of:
a rotation rate control signal with a reduced pulse frequency to the motor driving circuit; or
a power control signal with an increased pulse number to the power source driving circuit;
the power source driving circuit is further used to:
output a voltage signal with an increased amplitude in response to the power control signal with the increased pulse number; and
the motor driving circuit is further used to:
determine at least one of:
an adjusted frequency of the driving signal in response to the rotation rate control signal with the reduced pulse frequency; or
an adjusted amplitude of the driving signal in response to the voltage signal with the increased amplitude; and
output the adjusted driving signal.

5. The display apparatus according to claim 3, further comprising:
a distance sensor, connected to the motor controller, wherein the distance sensor is used to detect a distance between a fixed end and a movable end of the flexible display panel, and output a distance indication signal to the motor controller;
wherein the motor controller is further used to:
determine a movement distance of the flexible display panel based on the distance indication signal;
determine a current rotation rate of the motor based on the movement distance and a movement duration;
compare the current rotation rate with the first rotation rate; and
in response to a rotation rate difference between the current rotation rate and the first rotation rate being greater than or equal to a preset rotation rate threshold, output at least one of:
a rotation rate control signal with a reduced pulse frequency to the motor driving circuit; or
a power control signal with an increased pulse number to the power source driving circuit;
the power source driving circuit is further used to:
output a voltage signal with an increased amplitude in response to the power control signal with the increased pulse number; and
the motor driving circuit is further used to:
determine at least one of:
an adjusted frequency of the driving signal in response to the rotation rate control signal with the reduced pulse frequency; or
an adjusted amplitude of the driving signal in response to the voltage signal with the increased amplitude; and
output the adjusted driving signal, wherein an actual rotation rate of the motor in response to the adjusted driving signal matches with the first rotation rate.

6. The display apparatus according to claim 3, wherein the motor controller is further used to:
calculate a pulse number of the rotation rate control signal that is output cumulatively;
determine a movement distance of the flexible display panel based on the pulse number and a rotation rate of the motor;
compare the movement distance of the flexible display panel with a distance value of the first movement stage;
in response to the movement distance of the flexible display panel being equal to the distance value of the first movement stage, determine that the flexible display panel completes the first movement stage; or
in response to the movement distance of the flexible display panel being less than the distance value of the first movement stage, determine that the flexible display panel is in the first movement stage.

7. The display apparatus according to claim 2, wherein the motor is a stepping motor;
both the rotation rate control signal and the power control signal comprise periodic pulse signals; and
a ratio of the first rotation rate to the second rotation rate is greater than or equal to 0.5 and less than 1.

8.-9. (canceled)

10. A method for display panel movement control, applied to a display apparatus, comprising:
a flexible display panel;
a power device, connected to the flexible display panel, wherein the power device drives the flexible display panel to move in response to a driving signal; and
a control device, connected to the power device;
wherein the method is performed by the control device, and the method comprises:
controlling the power device to operate at a first rate in a first movement stage; and
controlling the power device to operate at a second rate in a second movement stage, wherein the second rate is greater than the first rate.

11. A method for display panel movement control, applied to a display apparatus, comprising:
a flexible display panel;
a power device, connected to the flexible display panel, wherein the power device drives the flexible display panel to move in response to a driving signal; and
a control device, connected to the power device; and
a push rod, connected to the flexible display panel;
wherein the power device comprises a motor, and a power end of the motor is connected to the push rod to drive the flexible display panel through the push rod;
the control device comprises:
a motor driving circuit, connected to the motor, wherein the motor driving circuit outputs a driving signal to the motor in response to a control signal; and
a motor controller, connected to the motor driving circuit;
wherein the method is performed by the motor controller, and the method comprises:
controlling, in a first movement stage, the motor to operate at a first rotation rate;
obtaining an actual rotation rate of the motor in real time;
in response to the actual rotation rate of the motor being less than the first rotation rate, controlling the motor driving circuit to output a driving signal for increasing a driving force to the motor to cause a rotation rate of the motor to match with the first rotation rate;
detecting, based on the driving signal, whether the flexible display panel completes the first movement stage; and
in response to the flexible display panel completing the first movement stage, controlling the motor to operate at a second rotation rate, until the flexible display panel completes a second movement stage, wherein the second rotation rate is greater than the first rotation rate.

12. The method according to claim 11, wherein the display apparatus further comprises a distance sensor, and the distance sensor is used to detect a distance between a fixed end and a movable end of the flexible display panel; and obtaining the actual rotation rate of the motor in real time comprises:
obtaining a distance indication signal output by the distance sensor in real time;
determining a movement distance of the flexible display panel based on the distance indication signal; and
determining the actual rotation rate of the motor based on the movement distance and a movement duration.

13. The method according to claim 12, wherein the method further comprises:
comparing the current rotation rate with the first rotation rate; and
in response to a rotation rate difference between the current rotation rate and the first rotation rate being greater than or equal to a preset rotation rate threshold, determining that the actual rotation rate of the motor is less than the first rotation rate.

14. The method according to claim 11, wherein the display apparatus further comprises a power source driving circuit, the power source driving circuit is connected to the motor controller and the motor driving circuit respectively, and controlling the motor driving circuit to output the driving signal for increasing the driving force to the motor, comprising:
outputting at least one of:
a rotation rate control signal with a reduced pulse frequency to the motor driving circuit; or
a power control signal with an increased pulse number to the power source driving circuit, wherein the power control signal is used to instruct the motor driving circuit to output a driving signal with an increased amplitude.

15. The method according to claim 11, wherein detecting, based on the driving signal, whether the flexible display panel completes the first movement stage, comprises:
calculating a pulse number of the rotation rate control signal that is output cumulatively;
determining a movement distance of the flexible display panel based on the pulse number and a rotation rate of the motor;
comparing the movement distance of the flexible display panel with a distance value of the first movement stage;
in response to the movement distance of the flexible display panel being equal to the distance value of the first movement stage, determining that the flexible display panel completes the first movement stage; or
in response to the movement distance of the flexible display panel being less than the distance value of the first movement stage, determining that the flexible display panel is in the first movement stage.

16. The method according to claim 11, wherein controlling the motor to operate at the first rotation rate comprises:
controlling the motor driving circuit to output a rotation rate control signal of a first frequency to the motor, wherein the rotation rate control signal of the first frequency is used to instruct the motor driving circuit to drive the motor to rotate at the first rotation rate; and
controlling the motor to operate at the second rotation rate comprises:
controlling the motor driving circuit to output a rotation rate control signal of a second frequency to the motor, wherein the second frequency is greater than the first frequency, and the rotation rate control signal of the second frequency is used to instruct the motor driving circuit to drive the motor to rotate at the second rotation rate.

17. The method according to claim 11, wherein the display apparatus further comprises a temperature sensor, and the temperature sensor is used to detect an ambient temperature of the display apparatus; and, the method further comprises:
obtaining a temperature indication signal output by the temperature sensor;
determining a current temperature based on the temperature indication signal; and
in response to the current temperature being less than a preset temperature threshold, controlling the motor driving circuit to output a driving signal for increasing a driving force to the motor, to cause an actual rotation rate of the motor to match with the first rotation rate.

18. The method according to claim 17, wherein controlling the motor driving circuit to output the driving signal for increasing the driving force to the motor comprises:
outputting at least one of:
a rotation rate control signal with a reduced pulse frequency to the motor driving circuit; or
a power control signal with an increased pulse number to the power source driving circuit, wherein the power control signal is used to instruct the motor driving circuit to output a driving signal with an increased amplitude.

19. (canceled)

20. A non-transitory computer-readable storage medium having a computer program stored thereon, wherein when the program is executed by a processor, the method for display panel movement control according to claim 10 is implemented.

21. A control device, comprising:
one or more processors; and
a storage apparatus, configured to store one or more programs, wherein when the one or more programs are executed by the one or more processors, the one or more processors are caused to implement the method for display panel movement control according to claim 10.

22. A non-transitory computer-readable storage medium having a computer program stored thereon, wherein when the program is executed by a processor, the method for display panel movement control according to claim 11 is implemented.

23. A control device, comprising:
one or more processors; and
a storage apparatus, configured to store one or more programs, wherein when the one or more programs are executed by the one or more processors, the one or more processors are caused to implement the method for display panel movement control according to claim 11.
